(19) United States
(12) Patent Application Publication
(10) Pub. No.: US 2025/0221206 A1
(43) Pub. Date: Jul. 3, 2025

(54) DISPLAY APPARATUS HAVING LINK WIRINGS

(71) Applicant: LG Display Co., Ltd., Seoul (KR)

(72) Inventors: Chan Soo PARK, Paju-si (KR); Cheol Woo PARK, Paju-si (KR); Gyu Sik WON, Paju-si (KR); Hyun Je BANG, Paju-si (KR)

(21) Appl. No.: 18/940,196

(22) Filed: Nov. 7, 2024

(30) Foreign Application Priority Data
Dec. 29, 2023 (KR) 10-2023-0197028

(51) Int. Cl. H10K 59/131

(52) U.S. Cl. CPC H10K 59/131

(57) ABSTRACT

In the display apparatus disclosed, each of pixel areas is electrically connected to a pad area by a link wiring. The pixel area is disposed in an active area. The pad area is disposed outside the active area. The link wiring includes a first, second, and third links. The first link can be disposed close to the pad area. The second link can be electrically connected to the first link. The third link can be electrically connected to the second link. The second link can include a first end electrically connected to the first link and a second end electrically connected to the third link. The second end of the second link can be disposed closer to pad area than the first end of the second link. Thus, in the display apparatus, a distance between the pad area and the active area can be reduced or minimized.

### CROSS-REFERENCE TO RELATED APPLICATIONS

This application claims the benefit of Korean Patent Application No. 10-2023-0197028, filed on Dec. 29, 2023, which is hereby incorporated by reference as if fully set forth herein.

### BACKGROUND

### Technical Field

The present disclosure relates to a display apparatus in which each of pixel areas is electrically connected to a pad area by one of link wirings.

### Description of the Related Art

Generally, a display apparatus provides an image to a user. For example, the display apparatus can include a plurality of pixel areas. Each of the pixel areas can realize a specific color. Various signal can be provided to each pixel area by signal wirings. The pixel areas can be disposed within an active area. For example, a pad area to which an external signal is applied can be disposed outside the active area.

Link wirings can be disposed between the active area and the pad area. For example, each of the pixel areas can be electrically connected to the pad area by one of the link wirings. The number of the link wirings can be proportion to the resolution of the display apparatus. A distance between adjacent link wirings can be a certain distance or more to prevent the distortion of signals applied through each link wiring. Thus, in the display apparatus, an area occupied by the link wirings can increase by the increase of the resolution. Therefore, in the display apparatus, the distance between the active area and the pad area can increase.

### BRIEF SUMMARY

Accordingly, the present disclosure is directed to a display apparatus that substantially obviates one or more problems due to limitations and disadvantages of the related art.

Various embodiments of the present disclosure provide a display apparatus capable of minimizing the distance between the active area and the pad area.

Various embodiments of the present disclosure provide a display apparatus in which the distance between adjacent link wirings can be maintained at a certain distance or more, and the area occupied by the link wirings between the active area and the pad part can be reduced or minimized.

Additional advantages, technical benefits, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these and other advantages, as embodied and broadly described herein, there is provided a display apparatus comprising a device substrate. The device substrate includes an active area and a bezel area. A pad area is disposed on the bezel area of the device substrate. A display device is disposed on a pixel area of the active area. A link wiring is disposed between the pad area and the active area. The link wiring electrically connects the pixel area to the pad area. The link wiring includes a first link, a second link and a third link. The first link is electrically connected to the pad area. The second link is electrically connected to the first link. The third link is electrically connected to the second link. A second end of the second link electrically connected to the third link is disposed closer to the pad area than a first end of the second link electrically connected to the first link.

The pad area can be spaced apart from the active area in a first direction. The second end of the second link can be spaced apart from the first end of the second link in a second direction. The second direction can be perpendicular to the first direction.

The second link can be disposed on a different layer from the first link. The third link can be disposed on a different layer from the second link.

The second link can include a different material from the first link. The third link can include a different material from the second link.

The display device can be electrically connected to a driving circuit. The driving circuit can include a thin film transistor. The thin film transistor can be disposed on the pixel area. A light-blocking pattern can be disposed between the device substrate and a semiconductor pattern of the thin film transistor. The first link can be disposed on a same layer as the light-blocking pattern. The second link can be disposed on a same layer as a drain electrode of the thin film transistor. The third link can be disposed on a same layer as a gate electrode of the thin film transistor.

The first link can include a same material as the light-blocking pattern. The second link can include a same material as the drain electrode. The third link can include a same material as the gate electrode.

The third link can be electrically connected to the driving circuit by a signal wiring. The signal link can be disposed on a same layer as the drain electrode.

The display device can include a light-emitting unit disposed between a first electrode and a second electrode.

In another embodiment, there is provided a display apparatus comprising a device substrate. Driving circuits and display devices are disposed on pixel areas of the device substrate. The driving circuit of each pixel area is electrically connected to the display device of the corresponding pixel area. Link wirings are disposed on a bezel area of the device substrate. The driving circuit of each pixel area is electrically connected to a pad area by one of the link wirings. Each of the link wirings includes a first link, a second link and a third link. The first link is disposed close to the pad area. The second link is electrically connected to the first link. The third link is electrically connected to the second link. An angle between the first link and the second link is an acute angle.

The angle between the first link and the second link in each link wiring can be proportional to a distance between the first link of the corresponding link wiring and the central region of the pad area.

The driving circuit of each pixel area can include a thin film transistor. A gate electrode of the thin film transistor can be disposed between the device substrate and a semiconductor pattern of the thin film transistor. The display device of each pixel area can include a pixel electrode and a common electrode. The pixel electrode of each pixel area can be electrically connected to a source electrode of the thin film transistor in the corresponding pixel area. The common electrode of each pixel area can be disposed between the device substrate and the pixel electrode of the corresponding pixel area.

The second link can be disposed on a same layer as the source electrode. At least one of first link and the third link can be disposed on a same layer as the common electrode.

The first link of each link wiring can be electrically connected to the pad area by one of output lines. The output lines can be disposed on a different layer from the first link, the second link and the third link.

The output lines can be disposed on a same layer as the gate electrode.

A distance between the third links of adjacent link wirings can be larger than a distance between the first links of the corresponding link wirings.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view schematically showing a cross-section of the pixel area in the display apparatus according to the embodiment of the present disclosure;

FIG. 4 is an enlarged view of K region in FIG. 1;

FIG. 5 is a view taken along I-I′ of FIG. 4; and

FIGS. 6 to 11 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

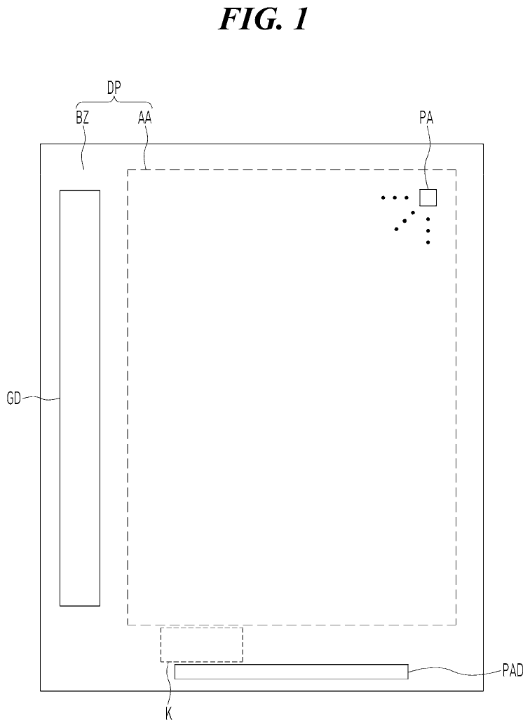

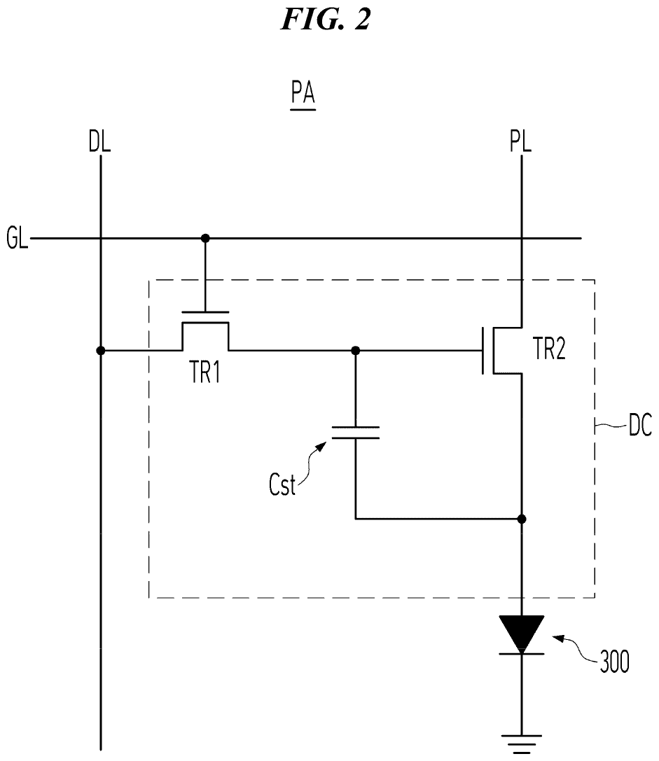

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, a plurality of pixel areas PA can be disposed in the display panel DP. Various signals can be provided in each pixel area PA through signal wirings GL, DL and PL. For example, the signal wirings GL, DL and PL can include gate lines GL applying a gate signal, data lines DL applying a data signal, and power voltage supply lines PL supplying a power voltage. The gate lines GL can be electrically connected to a gate driver GD. The data lines DL can be electrically connected to a data driver. The power voltage supply lines PL can be electrically connected to a power unit.

Each of the pixel areas PA can realize a specific color. For example, a driving circuit DC electrically connected to a display device 300 can be disposed in each pixel area PA. The driving circuit DC of each pixel area PA can be electrically connected to the signal wirings GL, DL and PL. For example, the driving circuit DC of each pixel area PA can be electrically connected to one of the gate lines GL, one of the data lines DL and one of the power voltage supply lines PL. The driving circuit DC of each pixel area PA can supply a driving current corresponding to the data signal to the display device 300 of the corresponding pixel area PA according to the gate signal for one frame. For example, the driving circuit DC of each pixel area PA can include a first thin film transistor TR1, a second thin film transistor TR2 and a storage capacitor Cst.

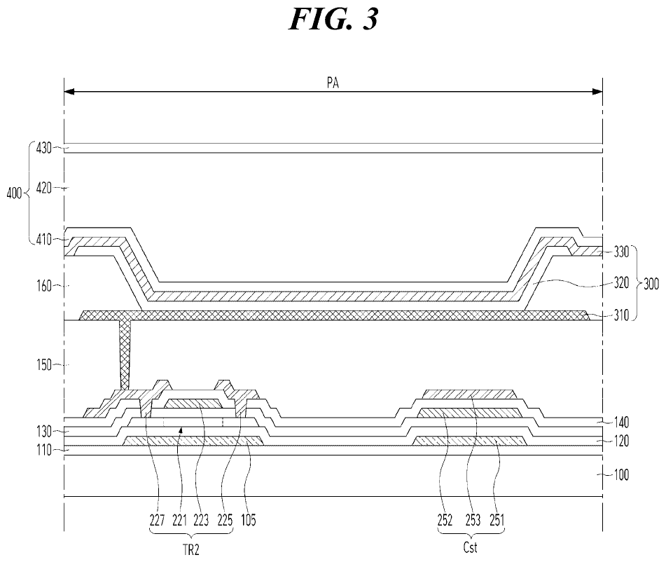

FIG. 3 is a view schematically showing a cross-section of the pixel area in the display apparatus according to the embodiment of the present disclosure.

Referring to FIGS. 2 and 3, the first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the corresponding gate line GL, and the first drain electrode can be electrically connected to the corresponding date line DL.

The first semiconductor pattern can include a semiconductor material. For example, the first semiconductor pattern can include amorphous silicon (a-Si), polycrystalline silicon (poly-Si) or an oxide semiconductor, such as IGZO. The first semiconductor pattern can include a first drain region, a first channel region and a first source region. The first channel region can be disposed between the first drain region and the first source region. A resistance of the first drain region and a resistance of the first source region can be smaller than a resistance of the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 can generate the driving current corresponding to the data signal. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the corresponding power voltage supply line PL.

The second semiconductor pattern 221 can include a semiconductor material. For example, the second semiconductor pattern 221 can include amorphous silicon (a-Si), polycrystalline silicon (poly-Si) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a resistance smaller than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can include a same material as the first drain electrode. The second drain electrode 225 can be disposed a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst can maintain a voltage applied to the second gate electrode 223 for one frame. For example, the storage capacitor Cst can be electrically connected to the second gate electrode 223 and the second source electrode 227 of the second thin film transistor TR2. The storage capacitor Cst can have a stacked structure of capacitor electrodes 251, 252 and 253. For example, the storage capacitor Cst include a second capacitor electrode 252 disposed on a first capacitor electrode 251 and a third capacitor electrode 253 disposed on the second capacitor electrode 252.

At least one of the capacitor electrodes 251, 252 and 253 of the storage capacitor Cst can be formed by using a process of forming the first thin film transistor TR1 and the second thin film transistor TR2. For example, the second capacitor electrode 252 can be disposed on a same layer as the second gate electrode 223, and the third capacitor electrode 253 can be disposed on a same layer as the second source electrode 227. The second capacitor electrode 252 can be electrically connected to the second gate electrode 223, and the third capacitor electrode 253 can be electrically connected to the second source electrode 227. The second capacitor electrode 252 can include a same material as the second gate electrode 223, and the third capacitor electrode 253 can include a same material as the second source electrode 227. The second capacitor electrode 252 can be formed by a same process as the second gate electrode 223, and the third capacitor electrode 253 can be formed by a same process as the second source electrode 227. For example, the second capacitor electrode 252 can be formed simultaneously with the second gate electrode 223, and the third capacitor electrode 253 can be formed simultaneously with the second source electrode 227.

The driving circuit DC of each pixel area PA can be disposed on a device substrate 100. For example, the first thin film transistor TR1, the second thin film transistor TR2 and the storage capacitor Cst of each pixel area PA can be supported by the device substrate 100. The device substrate 100 can include an insulating material. For example, the device substrate 100 can include glass or plastic.

A plurality of insulating layers 110, 120, 130, 140, 150 and 160 for preventing unnecessary electrical connection can be disposed on the device substrate 100. For example, a lower buffer layer 110, an upper buffer layer 120, a gate insulating layer 130, an interlayer insulating layer 140, a planarization layer 150 and a bank insulating layer 160 can be disposed on the device substrate 100.

The lower buffer layer 110 can be disposed close to the device substrate 100. The lower buffer layer 110 can prevent the pollution due to the device substrate 100 in a process of forming the driving circuit DC of each pixel area PA. For example, an upper surface of the device substrate 100 toward the driving circuit DC of each pixel area PA can be completely covered by the lower buffer layer 110. The driving circuit DC of each pixel area PA can be disposed on the lower buffer layer 110. The lower buffer layer 110 can include an insulating material. For example, the lower buffer layer 110 can include an inorganic insulating material, such as silicon oxide (SiOx) and silicon nitride (SiNx). The lower buffer layer 110 can have a multi-layer structure. For example, the lower buffer layer 110 can have a structure in which an inorganic insulating layer made of silicon oxide (SiOx) and an inorganic insulating layer made of silicon nitride (SiNx) are stacked.

The upper buffer layer 120 can be disposed on the lower buffer layer 110. The upper buffer layer 120 can include an insulating material. For example, the upper buffer layer 120 can include an inorganic insulating material, such as silicon oxide (SiOx) and silicon nitride (SiNx).

A light-blocking pattern 105 can be disposed between the lower buffer layer 110 and the upper buffer layer 120 of each pixel area PA. The light-blocking pattern 105 of each pixel area PA can include a material reflecting or absorbing light. For example, the light-blocking pattern 105 of each pixel area PA can include a metal. The light-blocking pattern 105 of each pixel area PA can overlap the second semiconductor pattern 221 of the corresponding pixel area PA. Thus, in the display apparatus according to the embodiment of the present disclosure, the light travelling toward the second semiconductor pattern 221 of each pixel area PA passing through the device substrate 100 can be blocked by the light-blocking pattern 105 of the corresponding pixel area PA. That is, in the display apparatus according to the embodiment of the present disclosure, the change in the characteristics of the second thin film transistor TR2 in each pixel area PA due to an external light can be prevented. Therefore, in the display apparatus according to the embodiment of the present disclosure, the reliability of the driving circuit DC in each pixel area PA can be improved.

The first capacitor electrode 251 of each pixel area PA can be disposed on a same layer as the light-blocking pattern 105 of the corresponding pixel area PA. For example, the first capacitor electrode 251 of each pixel area PA can be disposed between the lower buffer layer 110 and the upper buffer layer 120 of the corresponding pixel area PA. The first capacitor electrode 251 of each pixel area PA can include a same material as the light-blocking pattern 105 of the corresponding pixel area PA. The first capacitor electrode 251 of each pixel area PA can be formed by a same process as the light-blocking pattern 105 of the corresponding pixel area PA. For example, the first capacitor electrode 251 of each pixel area PA can be formed simultaneously with the light-blocking pattern 105 of the corresponding pixel area PA. Thus, in the display apparatus according to the embodiment of the present disclosure, a process of forming the driving circuit DC in each pixel area PA can be simplified. Therefore, in the display apparatus according to the embodiment of the present disclosure, the process efficiency can be improved.

The gate insulating layer 130 can be disposed on the upper buffer layer 120. The first gate electrode of each pixel area PA can be insulated from the first semiconductor pattern of the corresponding pixel area PA by the gate insulating layer 130. The second gate electrode 223 of each pixel area PA can be insulated from the second semiconductor pattern 221 of the corresponding pixel area PA by the gate insulating layer 130. For example, the gate insulating layer 130 can cover the first semiconductor pattern and the second semiconductor pattern 221 of each pixel area PA. The first gate electrode and the second gate electrode 223 of each pixel area PA can be disposed on the gate insulating layer 130. The gate insulating layer 130 can include an insulating material. For example, the gate insulating layer 130 can include an inorganic insulating material, such as silicon oxide (SiOx) and silicon nitride (SiNx).

The interlayer insulating layer 140 can be disposed on the gate insulating layer 130. The first drain electrode and the first source electrode of each pixel area PA can be insulated from the first gate electrode of the corresponding pixel area PA by the interlayer insulating layer 140. The second drain electrode 225 and the second source electrode 227 of each pixel area PA can be insulated from the second gate electrode 223 of the corresponding pixel area PA by the interlayer insulating layer 140. For example, the interlayer insulating layer 140 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 140. The interlayer insulating layer 140 can include an insulating material. For example, the interlayer insulating layer 140 can include an inorganic insulating material.

The planarization layer 150 can be disposed on the interlayer insulating layer 140. A thickness difference due to the driving circuit DC of each pixel area PA can be removed by the planarization layer 150. For example, an upper surface of the planarization layer 150 opposite to the device substrate 100 can be a flat surface. The upper surface of the planarization layer 150 can be parallel to the upper surface of the device substrate 100. The first drain electrode, the first source electrode, the second drain electrode 225 and the second source electrode 227 of each pixel area PA can be covered by the planarization layer 150. For example, the first drain electrode of each pixel area PA can be in direct contact with the first drain region of the corresponding pixel area PA by penetrating the gate insulating layer 130 and the interlayer insulating layer 140, and the first sourced electrode of each pixel area PA can be in direct contact with the first source region of the corresponding pixel area PA by penetrating the gate insulating layer 130 and the interlayer insulating layer 140. The second drain electrode 225 of each pixel area PA can be in direct contact with the second drain region of the corresponding pixel area PA by penetrating the gate insulating layer 130 and the interlayer insulating layer 140, and the second sourced electrode 227 of each pixel area PA can be in direct contact with the second source region of the corresponding pixel area PA by penetrating the gate insulating layer 130 and the interlayer insulating layer 140. The planarization layer 150 can include an insulating material. The planarization layer 150 can include a different material from the interlayer insulating layer 140. The planarization layer 150 can include a material having a relatively high fluidity. For example, the planarization layer 150 can include an organic insulating material.

The display device 300 of each pixel area PA can be disposed on the planarization layer 150. The display device 300 of each pixel area PA can emit light displaying a specific color. For example, the display device 300 of each pixel area PA can include a first electrode 310, a light-emitting unit 320 and a second electrode 330, which are sequentially stacked on the planarization layer 150 of the corresponding pixel area PA.

The first electrode 310 can include a conductive material. The first electrode 310 can include a material having a high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the first electrode 310 and the second electrode 330. For example, the light-emitting unit 320 can include an emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

A plurality of the emission material layer (EML) can be disposed within the light-emitting unit 320. For example, the light-emitting unit 320 can include a plurality of emission stacks having at least one emission material layer (EML) and at least one charge generation layer disposed between the emission stacks. The charge generation layer can supply electrons or holes to adjacent emission stack. Thus, in the display apparatus according to the embodiment of the present disclosure, the light can be emitted from each emission stack. The light emitted from each emission stack can display a same color. Therefore, in the display apparatus according to the embodiment of the present disclosure, the color reproduction can be improved.

The light-emitting unit 320 can include at least one functional layer. The functional layer can be one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting unit 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO, or a translucent electrode in which a metal, such as silver (Ag) and magnesium (Mg) is thinly formed. Thus, in the display apparatus according to the embodiment of the present disclosure, the light generated by the light-emitting unit 320 can be emitted outside through the second electrode 330.

The display device 300 of each pixel area PA can be electrically connected to the second thin film transistor TR2 of the driving circuit DC in the corresponding pixel area PA. For example, the first electrode 310 of each pixel area PA can be in direct contact with the second source electrode 227 of the corresponding pixel area PA by penetrating the planarization layer 150. The first electrode 310 of each pixel area PA can include a portion directly contacting the upper surface of the planarization layer 150. For example, the light-emitting unit 320 of the second electrode 330 of each pixel area PA can be stacked on a portion of the corresponding first electrode 310 directly contacting the upper surface of the planarization layer 150.

The bank insulating layer 160 can be disposed on the planarization layer 150. The bank insulating layer 160 can include an insulating material. For example, the bank insulating layer 160 can be an organic insulating material. The bank insulating layer 160 can include a different material from the planarization layer 150. The bank insulating layer 160 can define an emission area in each pixel area PA. For example, the first electrode 310 of each pixel area PA can be partially exposed by the bank insulating layer 160. An edge of the first electrode 310 in each pixel area PA can be covered by the bank insulating layer 160. Thus, in the display apparatus according to the embodiment of the present disclosure, the first electrode 310 of each pixel area PA can be insulated from the first electrode 310 of adjacent pixel area PA by the bank insulating layer 160.

A portion of the first electrode 310 exposed by the bank insulating layer 160 in each pixel area PA can overlap the emission area of the corresponding pixel area PA. A portion of the first electrode 310 overlapping with the emission area of each pixel area PA can be in direct contact with the upper surface of the planarization layer 150. That is, in the display apparatus according to the embodiment of the present disclosure, the light-emitting unit 320 and the second electrode 330 of each pixel area PA can be stacked on the emission area defined by the bank insulating layer 160 in the corresponding pixel area PA. Thus, in the display apparatus according to the embodiment of the present disclosure, the luminance deviation according to the generating location of the light emitted from each pixel area PA can be prevented.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. For example, the second electrode 330 of each pixel area PA can extend on the bank insulating layer 160. Thus, in the display apparatus according to the embodiment of the present disclosure, a process of forming the second electrode 330 in each pixel area PA can be simplified. And, in the display apparatus according to the embodiment of the present disclosure, the luminance of the light generated by the light-emitting unit 320 of each pixel area PA can be adjusted by the data signal applied to the driving circuit DC of the corresponding pixel area PA.

The image realized by the pixel areas PA can include various colors. The light emitted from the display device 300 of each pixel area PA can display a different color from the light emitted from the display device 300 of adjacent pixel area PA. For example, each of the pixel areas PA can be one of a red pixel area in which the light emitted from the display device 300 displays red color, a blue pixel area in which the light emitted from the display device 300 displays blue color, and a green pixel area in which the light emitted from the display device 300 displays green color. Some of the light-emitting unit 320 in each pixel area PA can be spaced apart from the light-emitting unit 320 of adjacent pixel area PA. For example, the emission material layer (EML) of each pixel area PA can be spaced apart from the emission material layer (EML) of adjacent pixel area PA. The light-emitting unit 320 of each pixel area PA can include an end disposed on the bank insulating layer 160.

An encapsulation structure 400 can be disposed on the display device 300 of each pixel area PA. The encapsulation structure 400 can prevent the damage of the display devices 300 due to the external moisture and impact. The encapsulation structure 400 can have a multi-layer structure. For example, the encapsulation structure 400 can have a stacked structure of a first encapsulating layer 410, a second encapsulating layer 420 and a third encapsulating layer 430. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the display devices 300 due to the external moisture and impact can be effectively prevented. A thickness difference due to the display device 300 of each pixel area PA can be removed by the second encapsulating layer 420. A thickness of the second encapsulating layer 420 can be greater than a thickness of the first encapsulating layer 410 and a thickness of the third encapsulating layer 430. For example, an upper surface of the encapsulation structure 400 opposite to the device substrate 100 can be a flat surface. The upper surface of the encapsulation structure 400 can be parallel to the upper surface of the device substrate 100.

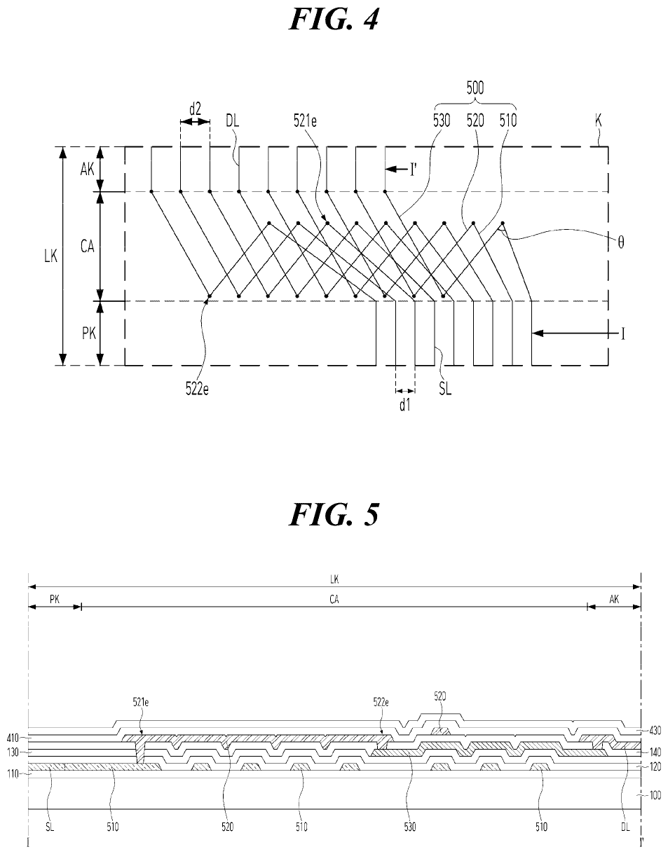

FIG. 4 is an enlarged view of K region in FIG. 1. FIG. 5 is a view taken along I-I′ of FIG. 4.

Referring to FIGS. 1 to 5, the display panel DP can include an active area AA in which the pixel areas PA are disposed, and a bezel area BZ disposed outside the active area AA. The bezel area BZ can be disposed outside the pixel areas PA. For example, the active area AA can be surrounded by the bezel area BZ. The gate driver GD, the data driver and the power unit can be disposed outside the active area AA. For example, each of the signal wirings GL, DL and PL can include a region disposed on the bezel area BZ.

At least one of the gate driver GD, the data driver and the power unit can be disposed on the bezel area BZ. For example, the display apparatus according to the embodiment of the present disclosure can be a GIP (Gate In Panel) type display apparatus in which the gate driver GD is formed on the bezel area BZ. The data driver and the power unit can be disposed outside the display panel DP. A pad area PAD to which the external signal is applied can be disposed on the bezel area BZ of the display panel DP.

The pad area PAD can be disposed on a side of the active area AA. For example, the pad area PAD can be disposed side by side with the active area AA in a first direction. A link area in which link wirings 500 are disposed can be disposed between the active area AA and the pad area PAD. The driving circuit DC of each pixel area PA can be electrically connected to the pad area PAD by one of the link wirings 500. For example, the data lines DL can be electrically connected to the pad area PAD by the link wirings 500. Each of the link wirings 500 can be electrically connected to one of output lines SL of the pad area PAD and one of the data lines DL. For example, the link area LK can include a pad connection region PK in which each of the link wirings 500 is electrically connected to one of the output lines SL of the pad area PAD, an active connection region AK in which each of the link wirings 500 is electrically connected to one of the data lines DL, and a central region CA disposed between the pad connection region PK and the active connection region AK. Each of the link wirings 500 can cross the central region CA of the link area LK.

Each of the link wirings 500 can include a first link 510, a second link 520 and a third link 530. The first link 510 of each link wiring 500 can be disposed close to the pad area PAD. For example, the first link 510 of each link wiring 500 can be electrically connected to one of the output lines SL in the pad connection region PK. The third link 530 of each link wiring 500 can be disposed close to the active area AA. For example, the third link 530 of each link wiring 500 can be electrically connected to one of the data lines DL in the active connection region AK. The second link 520 of each link wiring 500 can be disposed between the first link 510 and the third link 530 of the corresponding link wiring 500. For example, the second link 520 of each link wiring 500 can include a first end 521e electrically connected to the first link 510 of the corresponding link wiring 500 and a second end 522e electrically connected to the third link 530 of the corresponding link wiring 500. The second link 520 of each link wiring 500 can be disposed in the central region CA of the link area LK.

The second link 520 of each link wiring 500 can extend in a different direction from the first link 510 and the third link 530 of the corresponding link wiring 500. For example, the first link 510 and the third link 530 of each link wiring 500 can extend from the pad connection region PK toward the active connection region AK, and the second link 520 of each link wiring 500 can extend from the active connection region AK toward the pad connection region PK. The second end 522e of each second link 520 can be disposed closer to the pad area PAD than the first end 521e of the corresponding second link 520. For example, the first end 521e of each second link 520 can be disposed closer to the active connection region AK than the second end 522e of the corresponding second link 520, and the second end 522e of each second link 520 can be disposed closer to the pad connection region PK than the first end 521e of the corresponding second link 520. Thus, in the display apparatus according to the embodiment of the present disclosure, an area occupied by the link wirings 500 between the active area AA and the pad area PAD can be decreased by the second link 520 of each link wiring 500. Therefore, in the display apparatus according to the embodiment of the present disclosure, a distance between the active area AA and the pad area PAD can be reduced.

The second end 522e of each second link 520 can be spaced apart from the first end 521e of the corresponding second link 520 in a second direction perpendicular to the first direction. For example, an angle θ between the first link 510 and the second link 520 of each link wiring 500 can be larger than 0° and less than 90°. That is, in the display apparatus according to the embodiment of the present disclosure, the angle θ between the first link 510 and the second link 520 of each link wiring 500 can be an acute angle. Thus, in the display apparatus according to the embodiment of the present disclosure, a distance between the active area AA and the pad area PAD can be reduced, and a path of signal applied through each link wiring 500 can be moved in the second direction by the second link 520 of the corresponding link wiring 500.

The angle θ between the first link 510 and the second link 520 of each link wiring 500 can be proportional to a distance between the first link 510 of the corresponding link wiring 500 and the central region of the pad area PAD. For example, the angle θ between the first link 510 and the second link 520 of the link wiring 500 connected to the output line SL extending from an edge of the pad area PAD can be larger than the angle θ between the first link 510 and the second link 520 of the link wiring 500 connected to the output line SL extending from the central region of the pad area PAD. Thus, in the display apparatus according to the embodiment of the present disclosure, a distance d2 between adjacent data lines DL can be larger than a distance d1 between adjacent output lines SL. For example, in the display apparatus according to the embodiment of the present disclosure, a distance between the third links 530 of adjacent link wirings 500 can be larger than a distance between the first links 510 of adjacent link wirings 500. That is, in the display apparatus according to the embodiment of the present disclosure, a spaced distance between the link wirings 500 can be maintained at a certain distance or more, and an area occupied by the link wirings 500 between the active area AA and the pad area PAD can be reduced or minimized. Therefore, in the display apparatus according to the embodiment of the present disclosure, the distortion of the signal applied through each link wiring 500 can be prevented, and a distance between the active area AA and the pad area PAD can be reduced or minimized.

Accordingly, the display apparatus according to the embodiment of the present disclosure can include a plurality of the link wirings 500 electrically connecting each pixel area PA to the pad area PAD, wherein each of the link wirings 500 can include the first link 510 electrically connected to one of the output lines SL of the pad area PAD, the second link 520 electrically connected to the first link 510, and the third link 530 electrically connected to the second link 520, and wherein the angle θ between the first link 510 and the second link 520 of each link wiring 500 can have an acute angle. Thus, in the display apparatus according to the embodiment of the present disclosure, the area occupied by the link wirings 500 between the active area AA and the pad area PAD can be reduced or minimized, without the distortion of the signal applied through each link wiring 500. Therefore, in the display apparatus according to the embodiment of the present disclosure, the size of the bezel area BZ due to the increase in the number of the link wires 500 to realize high-resolution image can be reduced or minimized.

In the display apparatus according to the embodiment of the present disclosure, the second link 520 of each link wiring 500 can be disposed a different layer from the first link 510 of the corresponding link wiring 500, and the third link 530 of each link wiring 500 can be disposed on a different layer from the second link 520 of the corresponding link wiring 500. For example, the first link 510 of each link wiring 500 can be disposed on a same layer as the first capacitor electrode 251 of each pixel area PA, the second link 520 of each link wiring 500 can be disposed on a same layer as the third capacitor electrode 253 of each pixel area PA, and the third link 530 of each link wiring 500 can be disposed on a same layer as the second capacitor electrode 252 of each pixel area PA, as shown in FIGS. 3 to 5.

The planarization layer 150 and the bank insulating layer 160 can't extend onto the bezel area BZ. For example, the first link 510 of each link wiring 500 can be disposed between the lower buffer layer 110 and the upper buffer layer 120, the second link 520 of each link wiring 500 can be disposed between the interlayer insulating layer 140 and the first encapsulating layer 410, and the third link 530 of each link wiring 500 can be disposed between the gate insulating layer 130 and the interlayer insulating layer 140. The first link 510 of each link wiring 500 can include a same material as the light-blocking pattern 105 of each pixel area PA, the second link 520 of each link wiring 500 can include a same material as the second drain electrode 225 and the second source electrode 227 of each pixel area PA, and the third link 530 of each link wiring 500 can include a same material as the second gate electrode 223 of each pixel area PA. The first link 510 of each link wiring 500 can be formed by a same process as the light-blocking pattern 105 of each pixel area PA, the second link 520 of each link wiring 500 can be formed by a same process as the second drain electrode 225 and the second source electrode 227 of each pixel area PA, and the third link 530 of each link wiring 500 can be formed by a same process as the second gate electrode 223 of each pixel area PA. For example, the first link 510 of each link wiring 500 can be formed simultaneously with the light-blocking pattern 105 of each pixel area PA, the second link 520 of each link wiring 500 can be formed simultaneously with the second drain electrode 225 and the second source electrode 227 of each pixel area PA, and the third link 530 of each link wiring 500 can be formed simultaneously with the second gate electrode 223 of each pixel area PA. That is, in the display apparatus according to the embodiment of the present disclosure, the link wirings 500 in the link area LK can be formed by using a process of forming the light-blocking pattern 105 and the driving circuit DC in each pixel area PA.

A contact hole connecting the second end 522e of the second link 520 of each link wiring 500 to the third link 530 of the corresponding link wiring 500 and a contact hole connecting the first end 521e of the second link 520 of each link wiring 500 to the first link 510 of the corresponding link wiring 500 can be formed simultaneously with a contact hole connecting the second drain electrode 225 of each pixel area PA to the second drain region of the corresponding pixel area PA and a contact hole connecting the second source electrode 227 of each pixel area PA to the second source region of the corresponding pixel area PA. Thus, in the display apparatus according to the embodiment of the present disclosure, an additional process to the electric connection between the first link 510 and the second link 520 of each link wiring 500 and between the second link 520 and the third link 530 of each link wiring 500 can't be required. Therefore, in the display apparatus according to the embodiment of the present disclosure, the decrease in the process efficiency due to a process of forming the link wirings 500 can be prevented.

The output lines SL can be disposed on a same layer as the first link 510 of each link wiring 500. For example, the output lines SL can be disposed between the lower buffer layer 110 and the upper buffer layer 120. The output lines SL can include a same material as the first link 510 of each link wiring 500. The output lines SL can be formed by a same process as the first link 510 of each link wiring 500. For example, the output lines SL can be formed simultaneously with the first link 510 of each link wiring 500. The first link 510 of each link wiring 500 can be in direct contact with the corresponding output line SL. For example, a boundary between the first link 510 of each link wiring 500 and the corresponding output line SL can't be recognized. Thus, in the display apparatus according to the embodiment of the present disclosure, a resistance between the first link 510 of each link wiring 500 and the corresponding output line SL can be reduced or minimized. Thus, in the display apparatus according to the embodiment of the present disclosure, the delay of signal applied from the pad area PAD to each pixel area PA through each link wiring 500 can be reduced or minimized. And, in the display apparatus according to the embodiment of the present disclosure, an increase in the distance between the active area AA and the pad area PAD due to the electric connection between the link wirings 500 and the output lines SL can be prevented.

The data lines DL can be disposed on a same layer as the second drain electrode 225 and the second source electrode 227 of each pixel area PA. For example, the data lines DL can be disposed between the interlayer insulating layer 140 and the first encapsulating layer 410. A contact hole connecting each data line DL to the third link 530 of each link wiring 500 can be formed simultaneously with the contact hole connecting the second drain electrode 225 of each pixel area PA to the second drain region of the corresponding pixel area PA and the contact hole connecting the second source electrode 227 of each pixel area PA to the second source region of the corresponding pixel area PA. Thus, in the display apparatus according to the embodiment of the present disclosure, an additional process to the electric connection between the third link 530 of each link wiring 500 and the corresponding data line DL can't be required. Therefore, in the display apparatus according to the embodiment of the present disclosure, an decrease in the process efficiency due to the electric connection between the output lines SL and the data lines DL can be prevented.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to another embodiment of the present disclosure can include color filters disposed on a path of the light emitted from the display device 300 of each pixel area PA. For example, in the display apparatus according to another embodiment of the present disclosure, the color filters can be disposed on the encapsulation structure 400. The light passing through the color filter disposed on each pixel area PA can display a same color as the light emitted from the display device 300 of the corresponding pixel area PA. Thus, in the display apparatus according to another embodiment of the present disclosure, the color reproduction can be improved.

The display apparatus according to the embodiment of the present disclosure is described that the light emitted from the display device 300 of each pixel area PA can display a different color from the light emitted from the display device 300 of adjacent pixel area PA. However, in the display apparatus according to another embodiment of the present disclosure, the light emitted from the display device 300 of each pixel area PA can display a same color as the light emitted from the display device 300 of adjacent pixel area PA. For example, in the display apparatus according to the embodiment of the present disclosure, white light can be emitted from the display device 300 of each pixel area PA. That is, in the display apparatus according to another embodiment of the present disclosure, the image of various colors can be realized by the color filters disposed on the pixel areas PA. The light-emitting unit 320 of each pixel area PA can have a stacked structure same as the light-emitting unit 320 of adjacent pixel area PA. The light-emitting unit 320 of each pixel area PA can be formed by a same process as the light-emitting unit 320 of adjacent pixel area PA. For example, the light-emitting unit 320 of each pixel area PA can be formed simultaneously with the light-emitting unit 320 of adjacent pixel area PA. Thus, in the display apparatus according to another embodiment of the present disclosure, a process of forming the light-emitting unit 320 of each pixel area PA can be simplified. Therefore, in the display apparatus according to another embodiment of the present disclosure, the process efficiency can be improved.

The display apparatus according to the embodiment of the present disclosure is described that each of the link wirings 500 can include the first link 510, the second link 520 and the third link 530, which are disposed on a different layer from each other. However, in the display apparatus according to another embodiment of the present disclosure, each of the link wirings 500 can include a plurality of links 510, 520 and 530, and the plurality of links 510, 520 and 530 can be disposed on at least three different layers. For example, in the display apparatus according to another embodiment of the present disclosure, each of the link wirings 500 can include a fourth link disposed between the third link 530 and the corresponding data line DL, and the fourth link of each link wiring 500 can be disposed on a same layer as the first link 510 of the corresponding link wiring 500. Thus, in the display apparatus according to another embodiment of the present disclosure, the degree of freedom for the configuration of each link wiring 500 can be improved.

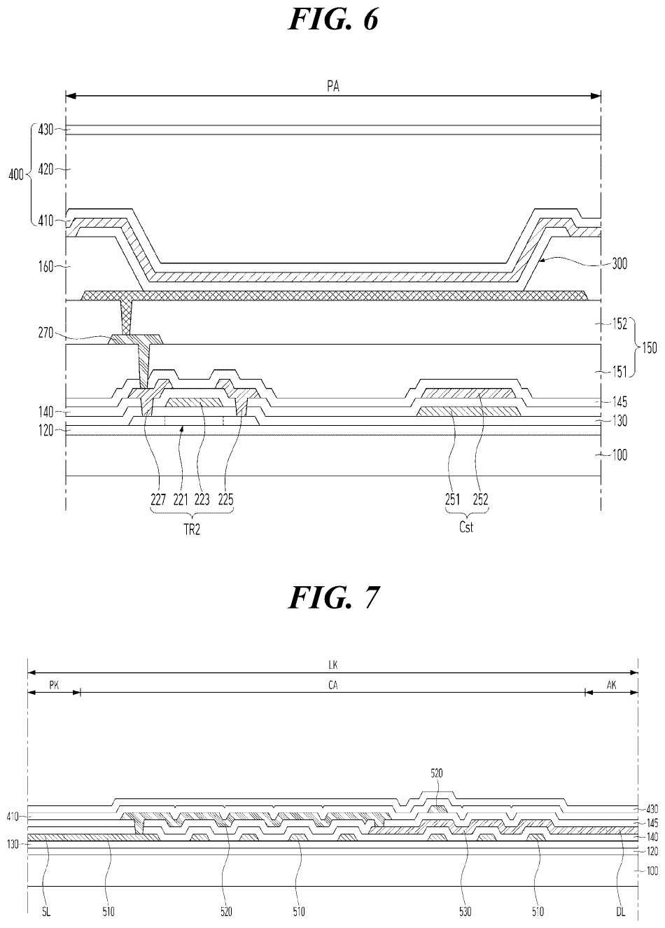

The display apparatus according to the embodiment of the present disclosure is described that the planarization layer 150 can be in direct contact with the first drain electrode, the first source electrode, the second drain electrode 225 and the second source electrode 227 of each pixel area PA. However, in the display apparatus according to another embodiment of the present disclosure, at least one insulating layer can be disposed between the interlayer insulating layer 140 and the planarization layer 150. For example, in the display apparatus according to another embodiment of the present disclosure, the first drain electrode, the first source electrode, the second drain electrode 225 and the second source electrode 227 of each pixel area PA can be covered by an intermediate insulating layer 145 disposed between the interlayer insulating layer 140 and the planarization layer 150, as shown in FIGS. 6 and 7. The intermediate insulating layer 145 can prevent the damage of the driving circuit DC in each pixel area PA due to the external impact and moisture. For example, the intermediate insulating layer 145 can extend along a surface of the driving circuit DC in each pixel area PA opposite to the device substrate 100. The intermediate insulating layer 145 can include an insulating material. For example, the intermediate insulating layer 145 can include an inorganic insulating material.

The third link 530 of each link wiring 500 can be disposed on a same layer as the data lines DL. For example, the output lines SL and the first link 510 of each link wiring 500 can be disposed between the gate insulating layer 130 and the interlayer insulating layer 140, the second link 520 of each link wiring 500 can be disposed between the intermediate insulating layer 145 and the first encapsulating layer 410, and the third link 530 of each link wiring 500 can be disposed between the interlayer insulating layer 140 and the intermediate insulating layer 145.

The lower buffer layer 110 of each pixel area PA can be omitted. The upper buffer layer 120 of each pixel area PA can be in direct contact with the upper surface of the device substrate 100. For example, the upper surface of the device substrate 100 can be completely covered by the upper buffer layer 120. The light-blocking pattern can't be formed in each pixel area PA. the storage capacitor Cst of each pixel area PA can have a stacked structure of the first capacitor electrode 251 disposed on a same layer as the second gate electrode 223 of the corresponding pixel area PA and the second capacitor electrode 252 disposed on a same layer as the second source electrode 227 of the corresponding pixel area PA. The second capacitor electrode 252 of each pixel area PA can be covered by the intermediate insulating layer 145. Thus, in the display apparatus according to another embodiment of the present disclosure, the degree of freedom for the configuration of the driving circuit and the stacked structure of the link wirings 500 can be improved.

The display apparatus according to the embodiment of the present disclosure is described that the first electrode 310 of each pixel area PA can be in direct contact with the second source electrode 227 of the corresponding pixel area PA. However, in the display apparatus according to another embodiment of the present disclosure, at least one conductive layer can be disposed between the first electrode 310 of each pixel area PA and the second source electrode 227 of the corresponding pixel area PA. For example, in the display apparatus according to another embodiment of the present disclosure, the planarization layer 150 can have a stacked structure of a lower planarization layer 151 and an upper planarization layer 152, an intermediate electrode 270 can be disposed between the lower planarization layer 151 and the upper planarization layer 152 of each pixel area PA, and the first electrode 310 of each pixel area PA can be electrically connected to the second source electrode 227 of the corresponding pixel area PA through the intermediate electrode 270 disposed on the corresponding pixel area PA, as shown in FIGS. 6 and 7. The intermediate electrode 270 of each pixel area PA can include a conductive material. For example, the intermediate electrode 270 of each pixel area PA can include a metal, such as aluminum (Al), chrome (Cr), copper (Cu), molybdenum (Mo), titanium (Ti) and tungsten (W). The intermediate electrode 270 of each pixel area PA can be in direct contact with the second source electrode 227 of the corresponding pixel area PA by penetrating the intermediate insulating layer 145 and the lower planarization layer 151. The first electrode 310 of each pixel area PA can be in direct contact with the intermediate electrode 270 of the corresponding pixel area PA by penetrating the upper planarization layer 152. Thus, in the display apparatus according to another embodiment of the present disclosure, the first electrode 310 of each pixel area PA can be stably connected to the second source electrode 227 of the corresponding pixel area PA. Therefore, in the display apparatus according to another embodiment of the present disclosure, the reliability of each pixel area PA can be improved.

The intermediate electrode 270 of each pixel area PA can include a same material as the second link 520 of each link wiring 500. The intermediate electrode 270 of each pixel area PA can be formed by a process same as the second link 520 of each link wiring 500. For example, the intermediate electrode 270 of each pixel area PA can be formed simultaneously with the second link 520 of each link wiring 500. Thus, in the display apparatus according to another embodiment of the present disclosure, the degree of freedom for the material of the second link 520 of each link wiring 500 can be improved.

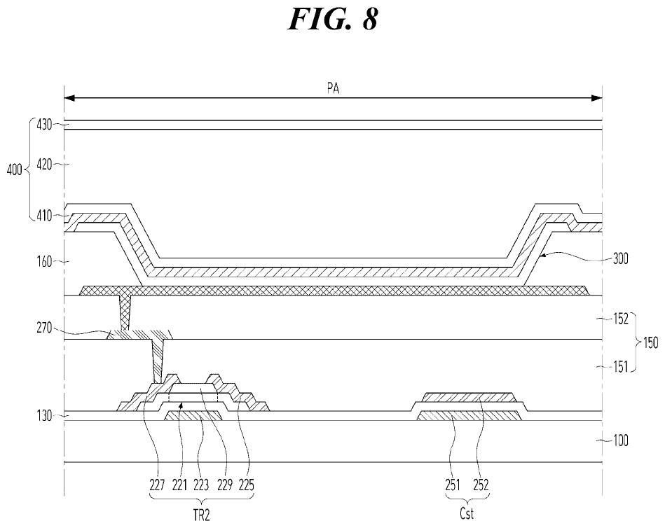

The display apparatus according to the embodiment of the present disclosure is described that the second semiconductor pattern 221 of each pixel area PA can be disposed between the device substrate 100 and the second gate electrode 223 of the corresponding pixel area PA. However, in the display apparatus according to another embodiment of the present disclosure, the first thin film transistor TR1 and the second thin film transistor TR2 of each pixel area PA can have various structures. For example, in the display apparatus according to another embodiment of the present disclosure, the second gate electrode 223 of each pixel area PA can be disposed closer to the device substrate 100 than the second semiconductor pattern 221 of the corresponding pixel area PA, as shown in FIG. 8. The second gate electrode 223 of each pixel area PA can be in direct contact with the upper surface of the device substrate 100. The second gate electrode 223 of each pixel area PA can be covered by the gate insulating layer 130. The second semiconductor pattern 221, the second drain electrode 225 and the second source electrode 227 of each pixel area PA can be disposed on the gate insulating layer 130. Each of the second drain electrode 225 and the second source electrode 227 in each pixel area PA can be in direct contact with a portion of the second semiconductor pattern 221 of the corresponding pixel area PA. For example, an etching stopper 229 can be disposed on the second channel region of the second semiconductor pattern 221 in each pixel area PA. Each of the second drain electrode 225 and the second source electrode 227 in each pixel area PA can include an end disposed on the etching stopper 229 of the corresponding pixel area PA. That is, in the display apparatus according to another embodiment of the present disclosure, the second thin film transistor TR2 of each pixel area PA can be a bottom gate type thin film transistor. The storage capacitor Cst of each pixel area PA can include the first capacitor electrode 251 disposed on a same layer as the second gate electrode 223 of the corresponding pixel area PA and the second capacitor electrode 252 disposed on a same layer as the second source electrode 227 of the corresponding pixel area PA. For example, in the display apparatus according to another embodiment of the present disclosure, the first capacitor electrode 251 of each pixel area PA can be disposed between the device substrate 100 and the gate insulating layer 130, and the second capacitor electrode 252 of each pixel area PA can be disposed between the gate insulating layer 130 and the planarization layer 150. Thus, in the display apparatus according to another embodiment of the present disclosure, the degree of freedom for the configuration of the driving circuit can be improved.

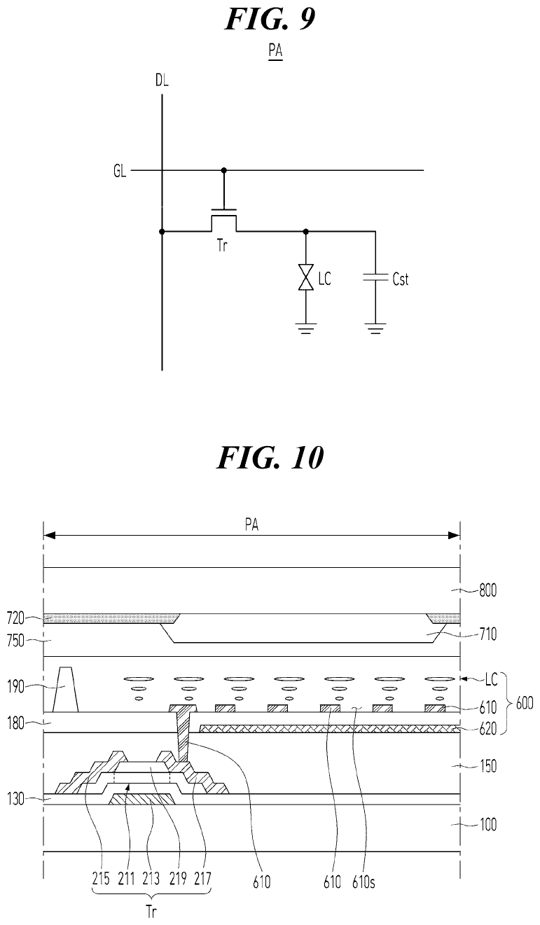

The display apparatus according to the embodiment of the present disclosure is described that the display device 300 of each pixel area PA can be a self-emission device in which the light-emitting unit 320 disposed between the first electrode 310 and the second electrode 330 includes at least one emission material layer (EML). However, in the display apparatus according to another embodiment of the present disclosure, the display device 300 of each pixel area PA can have various configurations. For example, in the display apparatus according to another embodiment of the present disclosure, the display device 300 of each pixel area PA can include a pixel electrode 610, a common electrode 620 and a liquid crystal layer LC disposed between the device substrate 100 and an encapsulation substrate 800, as shown in FIGS. 9 and 10. That is, the display apparatus according to another embodiment of the present disclosure can be a liquid crystal display apparatus including a liquid crystal panel.

The common electrode 620 of each pixel area PA can be disposed between the device substrate 100 and the pixel electrode 610 of the corresponding pixel area PA. For example, the pixel electrode 610 of each pixel area PA can be disposed on a device passivation layer 180 covering the common electrode 620 of the corresponding pixel area PA. The device passivation layer 180 can include an insulating material. For example, the device passivation layer 180 can include an inorganic insulating material and/or an organic insulating material. The common electrode 620 of each pixel area PA can be disposed between the planarization layer 150 and the device passivation layer 180. The pixel electrode 610 of each pixel area PA can include at least one slit 610s overlapping with the common electrode 620 of the corresponding pixel area PA. The liquid crystal layer LC of each pixel area PA can include a plurality of liquid crystal rotated by the horizontal electric field formed between the pixel electrode 610 and the common electrode 620 of the corresponding pixel area PA. For example, in the display apparatus according to another embodiment of the present disclosure, the liquid crystal layer LC of each pixel area PA can include a IPS mode liquid crystal.

Color filters 710, a black matrix 720 and a filter passivation layer 750 can be disposed on a surface of the encapsulation substrate 800 toward the liquid crystal layer LC of each pixel area PA. Each of the color filters 710 can overlap the display device 600 of each pixel area PA. For example, the pixel electrode 610 of each pixel area PA can include at least one slit 610s overlapping with the color filter 710 of the corresponding pixel area PA. The black matrix 720 can be disposed outside the display device 600 of each pixel area PA. Thus, in the display apparatus according to another embodiment of the present disclosure, the light leakage and the color mixing can be prevented. The filter passivation layer 750 can cover the color filters 710 and the black matrix 720. A thickness difference due to the color filters 710 and the black matrix 720 can be removed by the filter passivation layer 750. For example, a lower surface of the filter passivation layer 750 toward the device substrate 100 can be parallel to the upper surface of the device substrate 100. The filter passivation layer 750 can include an insulating material. For example, the filter passivation layer 750 can include an inorganic insulating material and/or an organic insulating material.

A spacer 190 overlapping with the black matrix 720 can be disposed between the device passivation layer 180 and the filter passivation layer 750. The spacer 190 can maintain a thickness of the liquid crystal layer LC in each pixel area PA. The spacer 190 can prevent the damage of the display device 600 in each pixel area PA due to the external impact. For example, the spacer 190 can be spaced apart from the filter passivation layer 750. The spacer 190 can include an insulating material. For example, the spacer 190 can include an inorganic insulating material and/or an organic insulating material. Thus, in the display apparatus according to another embodiment of the present disclosure, the degree of freedom for the configuration of the display device 600 in each pixel area PA can be improved.

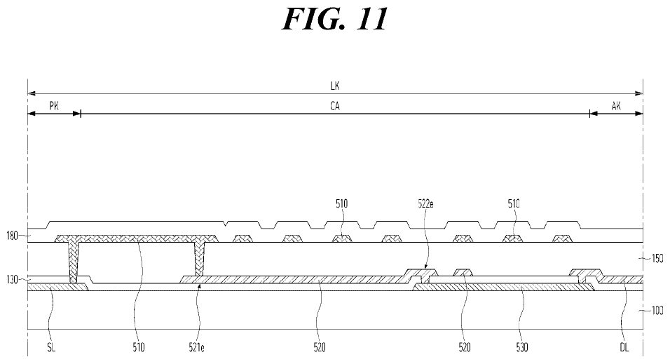

The display apparatus according to the embodiment of the present disclosure is described that the first link 510 of each link wiring 500 can be disposed on a same layer as the corresponding output line SL. However, in the display apparatus according to another embodiment of the present disclosure, the output lines SL can be disposed on a different layer from the first link 510 of each link wiring 500. For example, in the display apparatus according to another embodiment of the present disclosure, the first link 510 of each link wiring 500 can be disposed on a same layer as the common electrode 620 of each pixel area PA, the second link 520 of each link wiring 500 can be disposed on a same layer as a drain electrode 215 and a source electrode 217 of each pixel area PA, and the output lines SL and the third link 530 of each link wiring 500 can be disposed on a same layer as a gate electrode 213 of each pixel area PA, as shown in FIGS. 10 and 11.

The output lines SL and the third link 530 of each link wiring 500 can include a same material as the gate electrode 213 of each pixel area PA. The output lines SL and the third link 530 of each link wiring 500 can be formed by a same process as the gate electrode 213 of each pixel area PA. For example, the output lines SL and the third link 530 of each link wiring 500 can be formed simultaneously with the gate electrode 213 of each pixel area PA. The output lines SL, the third link 530 of each link wiring 500 and the gate electrode 213 of each pixel area PA can be in direct contact with the device substrate 100.

The first link 510 of each link wiring 500 can be disposed on the planarization layer 150 covering the second link 520 of each link wiring 500 and a thin film transistor Tr of each pixel area PA. For example, the first link 510 of each link wiring 500 can be disposed between the planarization layer 150 and the device passivation layer 180. The first link 510 of each link wiring 500 can include a same material as the common electrode 620 of each pixel area PA. The first link 510 of each link wiring 500 can be formed by a same process as the common electrode 620 of each pixel area PA. For example, the first link 510 of each link wiring 500 can be formed simultaneously with the common electrode 620 of each pixel area PA.

The data lines DL can be disposed on a same layer as the drain electrode 215 and the source electrode 217 of each pixel area PA. The second link 520 of each link wiring 500 can be disposed on a same layer as the data lines DL. For example, the second link 520 of each link wiring 500 and the data lines DL can be disposed between the gate insulating layer 130 and the planarization layer 150. The second link 520 of each link wiring 500 and the data lines DL can include a same material as the drain electrode 215 and the source electrode 217 of each pixel area PA. The second link 520 of each link wiring 500 and the data lines DL can be formed by a same process as the drain electrode 215 and the source electrode 217 of each pixel area PA. For example, the second link 520 of each link wiring 500 and the data lines DL can be formed simultaneously with the drain electrode 215 and the source electrode 217 of each pixel area PA. In the display apparatus according to another embodiment of the present disclosure, the area occupied by each link wiring 500 between the active area and the pad area can be reduced or minimized, regardless of the type of the thin film transistor Tr in each pixel area PA and the configuration of the display device 600. Therefore, in the display apparatus according to another embodiment of the present disclosure, the size of the bezel area can be reduced or minimized, without the distortion of the signal applied through each link wiring 500 in the display panel having various configurations to realize the image of high resolution.

In the result, the display apparatus according to the embodiments of the present disclosure can comprise the link wirings disposed between the active area and the pad area, wherein each of the link wirings can include the first link disposed close to the pad area, the second link electrically connected to the first link, and the third link electrically connected to the second link, and wherein the second end of the second link electrically connected to the third link can be disposed closer to the pad area than the first end of the second link electrically connected to the first link. Thus, in the display apparatus according to the embodiments of the present disclosure, the area occupied by the link wirings between the active area and the pad area can be reduced or minimized. Thereby, in the display apparatus according to the embodiments of the present disclosure, the distortion of the signal applied through each link wiring can be prevented, and the distance between the active area and the pad area can be reduced or minimized. And, in the display apparatus according to the embodiments of the present disclosure, the production energy can be reduced by process optimization.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a device substrate including an active area and a bezel area;
a pad area on the bezel area of the device substrate;
a display device on a pixel area of the active area; and
a link wiring between the pad area and the active area, the link wiring electrically connecting the pixel area to the pad area,
wherein the link wiring includes:
a first link electrically connected to the pad area,
a second link electrically connected to the first link, the second link having a first end and a second end, and
a third link electrically connected to the second link, and
wherein the second end of the second link electrically connected to the third link is disposed closer to the pad area than the first end of the second link electrically connected to the first link.

2. The display apparatus according to claim 1, wherein the pad area is spaced apart from the active area in a first direction, and
wherein the second end of the second link is spaced apart from the first end of the second link in a second direction transverse to the first direction.

3. The display apparatus according to claim 2, wherein the second end of the second link is spaced apart from the first end of the second link in a second direction perpendicular to the first direction.

4. The display apparatus according to claim 1, wherein the second link is on a different layer from the first link, and
wherein the third link is on a different layer from the second link.

5. The display apparatus according to claim 2, wherein the second link includes a different material from the first link, and
wherein the third link includes a different material from the second link.

6. The display apparatus according to claim 1, further comprising:
a driving circuit electrically connected to the display device, the driving circuit including a thin film transistor on the pixel area; and
a light-blocking pattern between the device substrate and a semiconductor pattern of the thin film transistor,
wherein the first link is on a same layer as the light-blocking pattern,
wherein the second link is on a same layer as a drain electrode of the thin film transistor, and
wherein the third link is on a same layer as a gate electrode of the thin film transistor.

7. The display apparatus according to claim 6, wherein the first link includes a same material as the light-blocking pattern, the second link includes a same material as the drain electrode, and the third link includes a same material as the gate electrode.

8. The display apparatus according to claim 6, further comprising a signal wiring electrically connecting the third link to the driving circuit,
wherein the signal wiring is on a same layer as the drain electrode.

9. The display apparatus according to claim 1, wherein the display device includes a light-emitting unit between a first electrode and a second electrode.

10. A display apparatus comprising:
driving circuits on pixel areas of a device substrate;
display devices on the pixel areas, each of the display device on each pixel area electrically connected to the driving circuit on the corresponding pixel area; and
link wirings on a bezel area of the device substrate, the link wirings electrically connecting the driving circuit of each pixel area to a pad area,
wherein each of the link wirings includes a first link disposed close to the pad area, a second link electrically connected to the first link and a third link electrically connected to the second link, the third link electrically connected to the driving circuits, and
wherein an angle between the first link and the second link is an acute angle.

11. The display apparatus according to claim 10, wherein the angle between the first link and the second link in each link wiring is proportional to a distance between the first link of the corresponding link wiring and the central region of the pad area.

12. The display apparatus according to claim 10, wherein the driving circuit of each pixel area includes a thin film transistor,
wherein a gate electrode of the thin film transistor is disposed between the device substrate and a semiconductor pattern of the thin film transistor, and
wherein the display device of each pixel area includes a pixel electrode electrically connected to a source electrode of the thin film transistor in the corresponding pixel area and a common electrode disposed between the device substrate and the pixel electrode of the corresponding pixel area.

13. The display apparatus according to claim 12, wherein the second link is on a same layer as the source electrode, and
wherein at least one of the first link and the third link is on a same layer as the common electrode.

14. The display apparatus according to claim 12, further comprising output lines electrically connected to the pad area and the first link of each link wiring,
wherein the output lines are on a different layer from the first link.

15. The display apparatus according to claim 14, wherein the output lines are on a same layer as the gate electrode.

16. The display apparatus according to claim 10, wherein a distance between the third links of adjacent link wirings is larger than a distance between the first links of the corresponding link wirings.

17. A display apparatus comprising:
driving circuits disposed on pixel areas of a device substrate;
display devices disposed on the pixel areas, each of the display device on each pixel area electrically connected to the driving circuit on the corresponding pixel area; and
link wirings disposed on a bezel area of the device substrate, the link wirings electrically connecting the driving circuit of each pixel area to a pad area,
wherein each of the link wirings includes a first link electrically connected to the pad area, a second link electrically connected to the first link and a third link electrically connected to the second link, the third link electrically connects to the driving circuits,
wherein the first link, the second link and the third link of the link wirings are arranged so that a distance between the third links of adjacent link wirings is larger than a distance between the first links of the adjacent link wirings.

18. The display apparatus according to claim 17, wherein an angle between the first link and the second link is in the range of 0° to 180°; and
an angle between the first link and the second link of a link wiring with a larger distance between the first link and the central region of the pad area is larger.

19. The display apparatus according to claim 17, further comprising output lines electrically connected to the pad area and the first link of each link wiring,
wherein the first link can be in contact with the corresponding output line.
